(19) United States
(12) Patent Application Publication
(10) Pub. No.: US 2026/0271433 A1
(43) Pub. Date: Sep. 10, 2026

(54) APPARATUS AND METHOD FOR OPTICALLY INSPECTING AND REMOVING MICRO LED ON SUBSTRATE

(71) Applicant: RAYLEIGH VISION INTELLIGENCE CO., LTD., HSINCHU CITY (TW)

(72) Inventor: Hung-Chih CHANG, HSINCHU CITY (TW)

(73) Assignee: RAYLEIGH VISION INTELLIGENCE CO., LTD., HSINCHU CITY (TW)

(21) Appl. No.: 19/556,747

(22) Filed: Mar. 4, 2026

(30) Foreign Application Priority Data
Mar. 5, 2025 (TW) 114108044

(51) Int. Cl. H10H 20/01; H10P 72/00

(52) U.S. Cl. CPC H10H 20/019; H10P 72/0428; H10P 72/0606

(57) ABSTRACT

An apparatus for optically inspecting and removing a micro-LED on a substrate is provided. The apparatus is configured to remove at least one defective chip among a plurality of micro-LEDs on the substrate. The apparatus comprises an image recognition module, a laser source, and a carrier platform. The image recognition module identifies the plurality of micro-LEDs and generates a chip positioning map, which includes the location of the at least one defective chip. The laser source emits a laser beam. The carrier platform moves the substrate according to the chip positioning map to align the at least one defective chip with the laser beam, thereby removing the at least one defective chip from the substrate. The carrier platform further moves the substrate to enable the image recognition module to capture a post-removal image of the location of the defective chip and verify the content of the post-removal image.

### CROSS-REFERENCE TO RELATED APPLICATION

This application claims priority from Taiwan Patent Application No. 114108044 filed on March 5, 2025, which are hereby incorporated herein by reference in its entirety.

### BACKGROUND OF THE INVENTION

### 1. Field of the Invention

The present disclosure relates to an apparatus and method for optical inspection and removal of micro light-emitting diodes (Micro-LEDs, μLEDs) on a substrate, and more particularly to an apparatus and method that utilize sensors to perform identification and verification before or after removing defective chips from the substrate.

### 2. Description of Related Art

In the field of light-emitting diode (LED) technology, the reduction of conventional LED sizes to the micrometer scale has led to the development of micro light-emitting diodes (Micro-LEDs, μLEDs). When applied in display technology, each Micro-LED can function as a sub-pixel in a display panel, forming what is known as a Micro-LED display. Due to their high luminous efficiency, long lifespan, and high resolution, Micro-LED displays are regarded as the next mainstream display technology.

The epitaxial process for Micro-LEDs typically employs techniques such as metal-organic chemical vapor deposition (MOCVD) to grow light-emitting structure layers on a supporting substrate. Before integrating each completed light-emitting unit (i.e., a single Micro-LED chip) into products with lighting or display functions, it is necessary to evaluate and classify each unit. This classification process generates a chip positioning map that includes the chip’s location and classification grade (or bin).

Chips identified as defective (or scrap dies) are removed from the carrier substrate using a laser removal machine. However, confirmation of whether the defective chips have been successfully removed still requires an additional inspection machine operating offline. Currently, Micro-LED removal machines and inspection machines are separate devices, necessitating the transfer of the carrier substrate between the two machines and repeated transmission and updating of the chip positioning map and related data.

### SUMMARY OF THE INVENTION

In one embodiment of the present disclosure, an apparatus for optically inspecting and removing a micro-LED on a substrate, configured to remove at least one defective chip among a plurality of micro-LEDs on the substrate, comprises: an image recognition module configured to identify the plurality of micro-LEDs and generate a chip positioning map, wherein the chip positioning map includes a location of the at least one defective chip; a laser source configured to emit a laser beam; and a carrier platform configured to move the substrate according to the chip positioning map to align the at least one defective chip with the laser beam, thereby removing the at least one defective chip from the substrate; wherein the carrier platform further moves the substrate to enable the image recognition module to capture a post-removal image of the location of the defective chip and verify the content of the post-removal image.

In another aspect of the present disclosure, the image recognition module comprises: a first image capturing unit disposed on the same side along with the laser source relative to the carrier platform; and a second image capturing unit disposed on a side opposite to the laser source relative to the carrier platform.

In another aspect of the present disclosure, the first image capturing unit is configured to capture a plurality of inspection images of the plurality of micro-LEDs, and the second image capturing unit is configured to capture the post-removal image at the location of the at least one defective chip.

In another aspect of the present disclosure, the first image capturing unit identifies the at least one defective chip and generates the chip positioning map based on the plurality of inspection images.

In another aspect of the present disclosure, the second image capturing unit updates the chip positioning map after verifying the content of the post-removal image.

In another aspect of the present disclosure, the first image capturing unit and the second image capturing unit comprise a visible light camera, a short-wave infrared camera, or a thermal imaging camera.

In another aspect of the present disclosure, the apparatus further comprises: a control module configured to generate control signals based on the chip positioning map; and a servo motor module configured to receive the control signals and move the carrier platform to a specific position.

In another aspect of the present disclosure, the chip positioning map includes positions or coordinates of the plurality of micro-LEDs and classified grades or bins of the plurality of micro-LEDs.

In another aspect of the present disclosure, when the image recognition module confirms that the content of the post-removal image matches one of specific patterns, the carrier substrate moves to realign the location of the at least one defective chip with the laser beam.

In another aspect of the present disclosure, the laser beam removes an entire or a residual part of the at least one defective chip from the carrier substrate.

In another aspect of the present disclosure, the image recognition module further comprises: a determination unit configured to identify the at least one defective chip, generate the chip positioning map, and verify the content of the post-removal image.

In one embodiment of the present disclosure, a method for optically inspecting and removing a micro-LED on a substrate, configured to remove at least one defective chip among a plurality of micro-LEDs on the substrate, comprises: identifying the plurality of micro-LEDs and generating a chip positioning map, wherein the chip positioning map includes a location of the at least one defective chip; moving the substrate according to the chip positioning map to align the at least one defective chip with a laser beam, thereby removing the at least one defective chip from the substrate; moving the substrate to capture a post-removal image of the location of the defective chip and verifying the content of the post-removal image; and returning to perform the step of removing the at least one defective chip when the content is confirmed to indicate an unsuccessful removal state for the at least one defective chip.

In another aspect of the present disclosure, the identifying step further comprises capturing a plurality of inspection images of the plurality of micro-LEDs to identify the at least one defective chip and generate the chip positioning map.

In another aspect of the present disclosure, the step of identifying further comprises executing an artificial intelligence model to recognize, confirm, and learn defect patterns.

In another aspect of the present disclosure, the step of verifying further comprises executing the artificial intelligence model to recognize and confirm whether the content of the post-removal image matches any one of the defect patterns.

In another aspect of the present disclosure, the content is confirmed to be at the unsuccessful removal state when the content of the post-removal image matches any one of the defect patterns.

In another aspect of the present disclosure, the step of identifying further comprises capturing inspection images of the plurality of micro-LEDs from the same side along with the laser beam relative to the substrate.

In another aspect of the present disclosure, the step of verifying further comprises capturing the post-removal image from a side opposite to the laser beam relative to the substrate.

In another aspect of the present disclosure, the chip positioning map is updated after the content is confirmed to be at the unsuccessful removal state.

In another aspect of the present disclosure, the chip positioning map includes positions or coordinates of the plurality of micro-LEDs and classified grades or bins of the plurality of micro-LEDs.

### BRIEF DESCRIPTION OF THE DRAWINGS

In order to sufficiently understand the essence, advantages and the preferred embodiments of the present invention, the following detailed description will be more clearly understood by referring to the accompanying drawings.

FIG. 1 is a schematic diagram illustrating an apparatus for optically inspecting and removing a micro-LED on a substrate according to one embodiment of the present disclosure.

FIG. 2 is a schematic diagram illustrating an apparatus for optically inspecting and removing a micro-LED on a substrate according to another embodiment of the present disclosure.

FIG. 3 is a flowchart illustrating a method for optically inspecting and removing a micro-LED on a substrate according to another embodiment of the present disclosure.

### DETAILED DESCRIPTION OF THE INVENTION

The following description shows the preferred embodiments of the present invention. The present invention is described below by referring to the embodiments and the figures. Thus, the present invention is not intended to be limited to the embodiments shown but is to be accorded the principles disclosed herein. Furthermore, various modifications or changes in light thereof will be suggested to a person skilled in the art and are to be included within the spirit and purview of this application and scope of the appended claims.

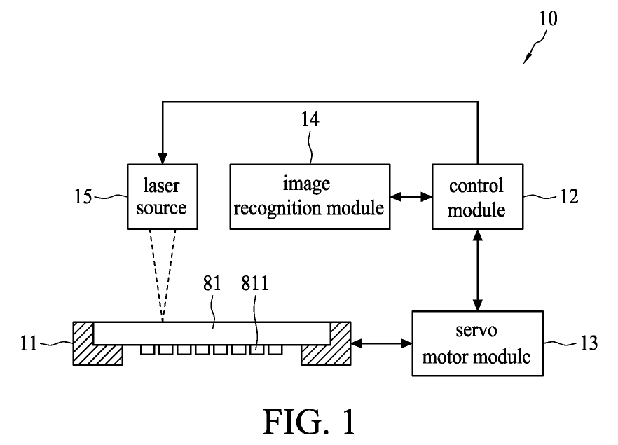

FIG. 1 is a schematic diagram illustrating an apparatus for optically inspecting and removing a micro-LED on a substrate according to one embodiment of the present disclosure. The apparatus 10 comprises a carrier platform 11, a control module 12, a servo motor module 13, an image recognition module 14, and a laser source 15. A plurality of chips 811 (micro-LED chips) are adhered to a carrier substrate 81, which is fixed on the carrier platform 11. The laser source 15 generates a laser beam and focuses it on the release layer of the carrier substrate 81. When the material absorbs energy and loses adhesion, the chip 811 aligned with the laser beam is removed from the carrier substrate 81. The servo motor module 13 enables the carrier platform 11 to move in a horizontal plane, thereby aligning a specific position of the carrier substrate 81 with the laser beam or with an image capturing unit of the image recognition module 14.

The image recognition module 14 comprises an image capturing unit and a determination unit, which identify the plurality of chips 811 on the substrate 81 to generate a chip positioning map or layout. The chip positioning map includes data such as the positions (or coordinates) and classification grades (or bins) of the plurality of chips 811 and may include the location of at least one defective chip. In addition, the image recognition module 14 may use an artificial intelligence model to recognize and confirm defect patterns (such as chip breakage or cracks) or types. The control module 12 generates control signals based on the chip positioning map, and the servo motor module 13 moves the carrier platform 11 to a specific position according to the control signals. For example, the carrier substrate 81 is moved so that a defective chip is aligned with the laser beam, thereby removing the defective chip from the carrier substrate 81. To confirm whether the defective chip has been successfully removed, the carrier platform 11 moves the carrier substrate 81 to enable the image recognition module 14 to capture a post-removal image of the location of the defective chip and verify whether the content of the post-removal image meets the pattern or conditions of successful removal. Furthermore, the verification of the post-removal image content may use an artificial intelligence model to recognize and confirm patterns (such as complete removal or partial residue) or types.

If it is determined that the defective chip has not been successfully removed or that a residue remains, the carrier substrate 81 is moved to realign the location of the defective chip with the laser beam, thereby removing the defective chip or the remaining portion from the carrier substrate 81. When it is determined that the defective chip has been successfully removed, the information in the chip positioning map is updated in real time, and the carrier substrate 81 is moved to align the next defective chip with the laser beam to perform the removal operation.

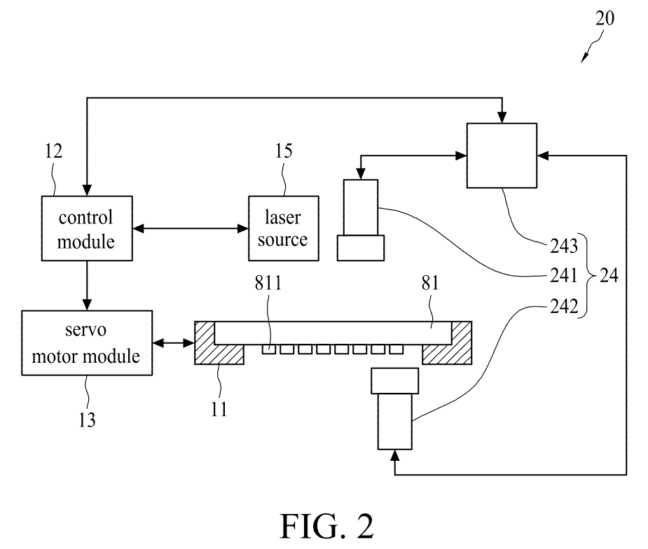

FIG. 2 is a schematic diagram illustrating an apparatus for optically inspecting and removing a micro-LED on a substrate according to another embodiment of the present disclosure. Compared with the embodiment shown in FIG. 1, the apparatus 20 of this embodiment includes an image recognition module 24 comprising a first image capturing unit 241, a second image capturing unit 242, and a determination unit 243. The first image capturing unit 241 is disposed on the same side along with the laser source 15 relative to the carrier platform 11, such as above the carrier platform 11 in the illustrated example. The second image capturing unit 242 is disposed on the side opposite to the laser source 15 relative to the carrier platform 11, such as below the carrier platform 11 in the illustrated example.

Before performing the defective chip removal operation, the first image capturing unit 241 captures a plurality of inspection images of the plurality of chips 811, enabling the determination unit 243 to identify defective chips and generate the chip positioning map. The second image capturing unit 242 captures a post-removal image at the location of the defective chip, and the determination unit 243 recognizes and verifies the content of the post-removal image. The first image capturing unit 241 and the second image capturing unit 242 may be a visible light camera, a short-wave infrared camera, a thermal imaging camera, or a non-optical sensor.

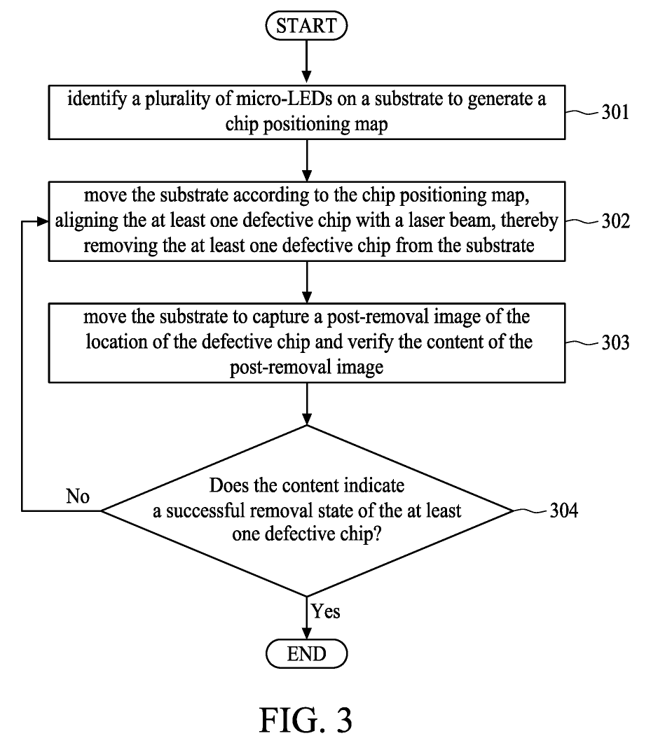

To remove at least one defective chip among a plurality of micro-LEDs on a substrate, FIG. 3 is a flowchart illustrating a method for optically inspecting and removing a micro-LED on a substrate according to another embodiment of the present disclosure. Referring to step 301, the plurality of micro-LEDs are identified to generate a chip positioning map, wherein the chip positioning map includes the location of the at least one defective chip, as described in detail in the previous two embodiments. Next, step 302 is performed to move the substrate according to the chip positioning map, aligning the at least one defective chip with a laser beam, thereby removing the at least one defective chip from the substrate. Then, step 303 is performed to move the substrate to capture a post-removal image of the location of the defective chip and verify the content of the post-removal image. When the content indicates a successful removal state of the at least one defective chip, the removal or elimination operation of the defective chip is completed, as shown in step 304. If another defective chip needs to be removed, steps 302 to 304 may be repeated. Conversely, if the at least one defective chip has not been successfully removed, steps 302 to 304 are repeated.

Although the present disclosure has been described with reference to specific embodiments and implementations, those skilled in the art may propose various changes and modifications. It is intended that the present disclosure encompass such changes and modifications that fall within the scope of the appended claims.

What is claimed is:

1. An apparatus for optically inspecting and removing a micro-LED on a substrate, configured to remove at least one defective chip among a plurality of micro-LEDs on the substrate, comprising:
an image recognition module configured to identify the plurality of micro-LEDs and generate a chip positioning map, wherein the chip positioning map includes a location of the at least one defective chip;
a laser source configured to emit a laser beam; and
a carrier platform configured to move the substrate according to the chip positioning map to align the at least one defective chip with the laser beam, thereby removing the at least one defective chip from the substrate;
wherein the carrier platform further moves the substrate to enable the image recognition module to capture a post-removal image of the location of the defective chip and to verify the content of the post-removal image.

2. The apparatus of claim 1, wherein the image recognition module comprises:
a first image capturing unit disposed on a same side along with the laser source relative to the carrier platform; and
a second image capturing unit disposed on a side opposite to the laser source relative to the carrier platform.

3. The apparatus of claim 2, wherein the first image capturing unit is configured to capture a plurality of inspection images of the plurality of micro-LEDs, and the second image capturing unit is configured to capture the post-removal image at the location of the at least one defective chip.

4. The apparatus of claim 3, wherein the first image capturing unit identifies the at least one defective chip and generates the chip positioning map based on the plurality of inspection images.

5. The apparatus of claim 4, wherein the second image capturing unit updates the chip positioning map after verifying the content of the post-removal image.

6. The apparatus of claim 5, wherein the first image capturing unit and the second image capturing unit comprise a visible light camera, a short-wave infrared camera, or a thermal imaging camera.

7. The apparatus of claim 1, further comprising:
a control module configured to generate control signals based on the chip positioning map; and
a servo motor module configured to receive the control signals and move the carrier platform to a specific position.

8. The apparatus of claim 1, wherein the chip positioning map includes positions or coordinates of the plurality of micro-LEDs and classified grades or bins of the plurality of micro-LEDs.

9. The apparatus of claim 1, wherein when the image recognition module confirms that the content of the post-removal image matches one of specific patterns, the substrate moves to realign the location of the at least one defective chip with the laser beam.

10. The apparatus of claim 1, wherein the laser beam removes an entire or a residual part of the at least one defective chip from the substrate.

11. The apparatus of claim 2, wherein the image recognition module further comprises:
a determination unit configured to identify the at least one defective chip, generate the chip positioning map, and verify the content of the post-removal image.

12. A method for optically inspecting and removing a micro-LED on a substrate, configured to remove at least one defective chip among a plurality of micro-LEDs on the substrate, comprising:
identifying the plurality of micro-LEDs and generating a chip positioning map, wherein the chip positioning map includes a location of the at least one defective chip;
moving the substrate according to the chip positioning map to align the at least one defective chip with a laser beam, thereby removing the at least one defective chip from the substrate;
moving the substrate to capture a post-removal image of the location of the defective chip and verifying the content of the post-removal image; and
returning to perform the step of removing the at least one defective chip when the content is confirmed to indicate an unsuccessful removal state for the at least one defective chip.

13. The method of claim 12, wherein the identifying step further comprises:
capturing a plurality of inspection images of the plurality of micro-LEDs to identify the at least one defective chip and generate the chip positioning map.

14. The method of claim 13, wherein the step of identifying further comprises executing an artificial intelligence model to recognize, confirm, and learn defect patterns.

15. The method of claim 14, wherein the step of verifying further comprises executing the artificial intelligence model to recognize and confirm whether the content of the post-removal image matches any one of the defect patterns.

16. The method of claim 15, wherein the content is confirmed to be at the unsuccessful removal state when the content of the post-removal image matches any one of the defect patterns.

17. The method of claim 12, wherein the step of identifying further comprises capturing inspection images of the plurality of micro-LEDs from the same side along with the laser beam relative to the substrate.

18. The method of claim 12, wherein the step of verifying further comprises capturing the post-removal image from a side opposite to the laser beam relative to the substrate.

19. The method of claim 12, wherein the chip positioning map is updated after the content is confirmed to be at the unsuccessful removal state.

20. The method of claim 19, wherein the chip positioning map includes positions or coordinates of the plurality of micro-LEDs and classified grades or bins of the plurality of micro-LEDs.
